(19) United States
(12) Patent Application Publication
(10) Pub. No.: US 2010/0295151 A1
(43) Pub. Date: Nov. 25, 2010

(54) SEMICONDUCTOR DEVICE

(75) Inventor: Hiromasa KUROKAWA, Niigata (JP)

Correspondence Address: McDERMOTT WILL & EMERY LLP, 600 13th Street, N.W., Washington, DC, 20005-3096, US

(73) Assignee: PANASONIC CORPORATION, Osaka (JP)

(21) Appl. No.: 12/849,578

(22) Filed: Aug. 3, 2010

Related U.S. Application Data
(63) Continuation of application No. PCT/JP2009/003156, filed on Jul. 7, 2009.

(30) Foreign Application Priority Data
Oct. 31, 2008 (JP) 2008-281783

(51) Int. Cl. H01L 29/86

(52) U.S. Cl. 257/531; 257/E29.325

(57) ABSTRACT

A semiconductor device includes a first substrate having a first surface on which a passive element is formed and a second surface on which a shield layer is formed, and a second substrate having a first surface on which an active element is formed. The first substrate is mounted on the second substrate with the second surface of the first substrate facing the second substrate.

### CROSS-REFERENCE TO RELATED APPLICATIONS

This is a continuation of PCT International Application PCT/JP2009/003156 filed on Jul. 7, 2009, which claims priority to Japanese Patent Application No. 2008-281783 filed on Oct. 31, 2008. The disclosures of these applications including the specifications, the drawings, and the claims are hereby incorporated by reference in their entirety.

### BACKGROUND

There is a demand for a single semiconductor device including both active elements, such as a transistor and the like, and passive elements, such as an inductor, a capacitor, a resistor, and the like, to implement a circuit, such as a matching circuit, a filter, or the like, in order to reduce the size, the weight, and the power consumption.

In recent years, to meet this demand, passive elements, such as an inductor and the like, have been formed on a semiconductor substrate on which active elements are formed with an insulating resin layer being interposed therebetween. In such a semiconductor device, particularly a high-frequency IC for millimeter waveband or the like, there are a loss due to parasitic capacitance between the inductor and the semiconductor substrate, a loss due to eddy current occurring in the semiconductor substrate, and the like, resulting in a decrease in the Q factor. Therefore, in the semiconductor device, the parasitic capacitance and the eddy current are reduced by increasing the distance between the inductor and the semiconductor substrate, and the eddy current is reduced by using a semiconductor substrate having a high specific resistance. See, for example, Japanese Patent Laid-Open Publication No. 2003-86690.

### SUMMARY

On the other hand, there is a problem with the aforementioned semiconductor device that magnetic flux which is generated by the inductor to pass through the semiconductor substrate has an influence on the active elements, such as a transistor and the like, which are formed on the semiconductor substrate, so that the active elements malfunction. Therefore, in general semiconductor devices, when the inductor is formed directly above the semiconductor substrate with an insulating resin layer or the like being interposed therebetween, the inductor needs to be disposed directly above a region of the semiconductor substrate in which the active elements, such as a transistor and the like, are not formed, in order to avoid the influence of the magnetic flux generated by the inductor. In other words, the layout is not flexible, leading to an increase in the chip area.

In view of the foregoing, the detailed description describes implementations of a semiconductor device in which magnetic flux generated by an inductor is hindered or prevented from affecting an active element provided on a semiconductor substrate below the inductor, whereby the inductor can be disposed at substantially any location on the semiconductor substrate.

An example semiconductor device includes a first substrate having a first surface on which a passive element is formed and a second surface on which a shield layer is formed, and a second substrate having a first surface on which an active element is formed and a second surface. The first substrate is mounted on the second substrate with the second surface of the first substrate facing the second substrate.

In the example semiconductor device, magnetic flux generated by the passive element of the first substrate can be interrupted by the shield layer, whereby the active element of the second substrate can be hindered or prevented from being affected by the magnetic flux. Therefore, the active element of the second substrate can be disposed at substantially any location irrespective the location of the passive element on the first substrate.

Note that the example semiconductor device preferably further includes at least one second through-via penetrating the second substrate.

In this case, the semiconductor device can be mounted onto a mounting substrate via the at least one second through-via exposed on the second surface of the second substrate opposite to the first surface on which the active element is formed.

The example semiconductor device preferably further includes at least one first through-via penetrating the first substrate. The passive element is preferably electrically connected to the at least one second through-via via the at least one first through-via. Moreover, the passive element is preferably electrically connected to the at least one second through-via, but not via interconnects in integrated circuits formed in the first and second substrates.

Interconnects in integrated circuits have a narrower width than that of through-vias and the like. Therefore, for example, there is a large transmission loss for a high frequency signal. Therefore, by electrically connecting the passive element to the at least one second through-via via the at least first through-vias, but not via the interconnects in the integrated circuits, the transmission loss due to the parasitic resistance can be reduced or avoided.

The shield layer is preferably electrically connected to the at least one second through-via. Moreover, the shield layer is preferably electrically connected to the at least one second through-via, but not via interconnects in integrated circuits formed in the first and second substrates.

In this case, it is possible to reduce or avoid the influence of the parasitic resistance of the interconnects in the integrated circuits.

The semiconductor device is preferably connected to a mounting substrate via the at least one second through-via exposed on the second surface of the second substrate.

In this case, it is possible to incorporate the semiconductor device into a small-size package, such as a chip scale package (CSP) or the like, resulting in a smaller mounting area.

The first substrate is preferably an insulating substrate.

The passive element provided on the first substrate is preferably an inductor.

The shield layer is preferably a metal layer.

In this case, the effect of the shield layer interrupting the magnetic flux generated by the passive element is significantly enhanced.

According to the aforementioned example semiconductor device, the magnetic flux generated by the passive element formed on the first substrate can be interrupted by the shield layer, whereby the active element formed on the second substrate can be hindered or prevented from being affected by the magnetic flux. Therefore, it is possible to achieve flexible layout without a limitation on the arrangement of the passive element and the active element, resulting in a smaller multilayer semiconductor device in which substrates are stacked in the thickness direction.

### BRIEF DESCRIPTION OF THE DRAWINGS

FIG. 1 is a cross-sectional view showing an example semiconductor device according to a first embodiment of the present disclosure.

FIG. 2 is a plan view showing a structure of the example semiconductor device of the first embodiment of the present disclosure and an example semiconductor device according to a second embodiment of the present disclosure.

FIG. 3 is a cross-sectional view of a first substrate in the first embodiment of the present disclosure.

FIG. 4 is a plan view of the first substrate in the first embodiment of the present disclosure as viewed from one side.

FIG. 5 is a plan view of the first substrate in the first embodiment of the present disclosure as viewed from the other side.

FIG. 6 is a diagram showing a first variation of the first substrate in the first embodiment of the present disclosure.

FIG. 7 is a plan view of a second variation of the first substrate in the first embodiment of the present disclosure as viewed from one side.

FIG. 8 is a plan view of the second variation of the first substrate in the first embodiment of the present disclosure as viewed from the other side.

FIG. 9 is a graph showing example characteristics indicating the dependency of the Q factor of an inductor on an inductor-shield distance.

FIG. 10 is a diagram for describing a method for fabricating the first substrate in the first embodiment of the present disclosure.

FIG. 11 is a diagram for describing the method for fabricating the first substrate in the first embodiment of the present disclosure.

FIG. 12 is a diagram for describing the method for fabricating the first substrate in the first embodiment of the present disclosure.

FIG. 13 is a diagram for describing the method for fabricating the first substrate in the first embodiment of the present disclosure.

FIG. 14 is a diagram for describing the method for fabricating the first substrate in the first embodiment of the present disclosure.

FIG. 15 is a diagram for describing the method for fabricating the first substrate in the first embodiment of the present disclosure.

FIG. 16 is a diagram for describing the method for fabricating the first substrate in the first embodiment of the present disclosure.

FIG. 17 is a diagram for describing the method for fabricating the first substrate in the first embodiment of the present disclosure.

FIG. 18 is a diagram for describing the method for fabricating the first substrate in the first embodiment of the present disclosure.

FIG. 19 is a diagram for describing the method for fabricating the first substrate in the first embodiment of the present disclosure.

FIG. 20 is a diagram for describing the method for fabricating the first substrate in the first embodiment of the present disclosure.

FIG. 21 is a cross-sectional view showing an example semiconductor device according to a second embodiment of the present disclosure.

FIG. 22 is a diagram for describing a method for fabricating a second substrate in the second embodiment of the present disclosure.

FIG. 23 is a diagram for describing the method for fabricating the second substrate in the second embodiment of the present disclosure.

FIG. 24 is a diagram for describing the method for fabricating the second substrate in the second embodiment of the present disclosure.

FIG. 25 is a diagram for describing the method for fabricating the second substrate in the second embodiment of the present disclosure.

FIG. 26 is a diagram for describing the method for fabricating the second substrate in the second embodiment of the present disclosure.

FIG. 27 is a diagram for describing the method for fabricating the second substrate in the second embodiment of the present disclosure.

### DETAILED DESCRIPTION

### First Embodiment

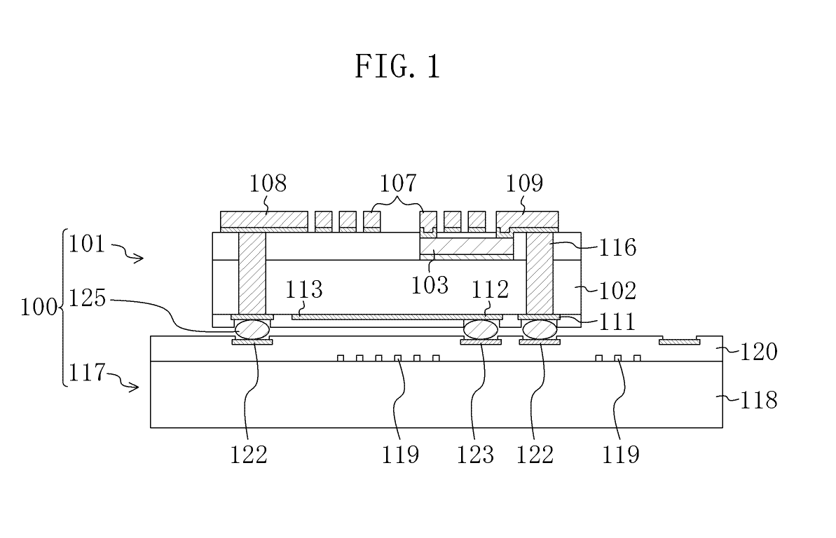

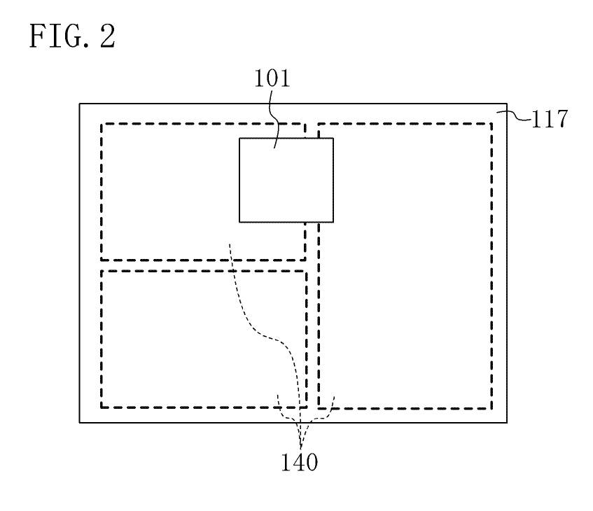

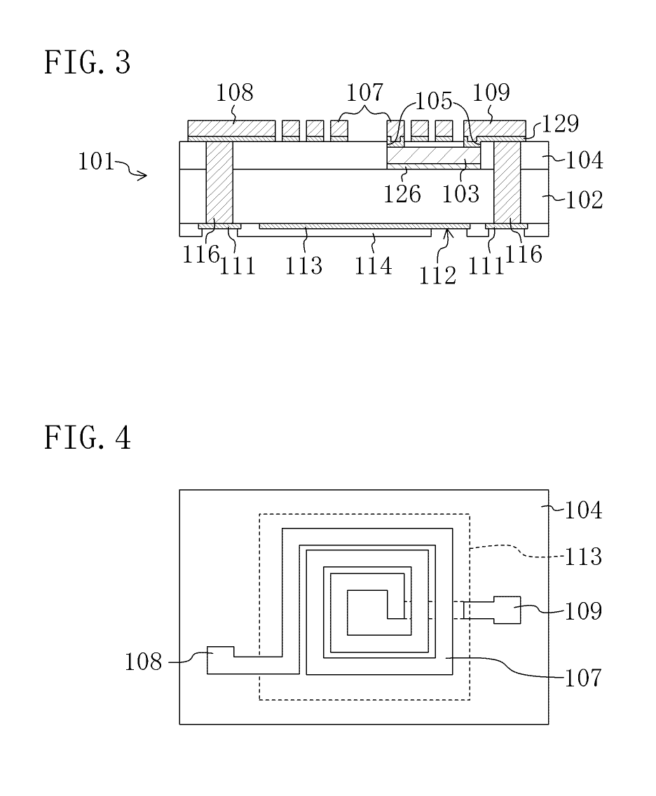

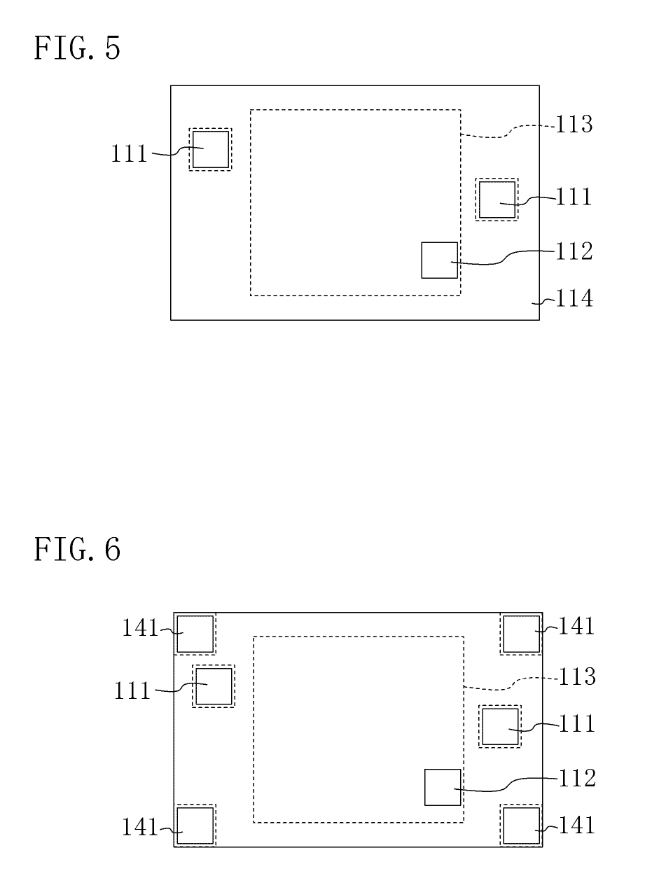

A semiconductor device according to a first embodiment of the present disclosure will be described hereinafter with reference to the accompanying drawings. FIG. 1 is a cross-sectional view showing the semiconductor device 100 of this embodiment. FIG. 2 is a plan view of the semiconductor device 100 as viewed from the top. As shown in FIGS. 1 and 2, the semiconductor device 100 has a structure in which a first substrate 101 is mounted on a second substrate 117 with metal bumps 125 being interposed therebetween. FIG. 3 is a cross-sectional view showing a structure of the first substrate 101. FIGS. 4 and 5 are plan views of the first substrate 101 as viewed from the top and the bottom, respectively. Note that the figures are all schematic and are not necessarily to the same scale.

The first substrate 101 shown in FIGS. 3, 4, and 5 will be described. The first substrate 101 includes an insulating substrate 102. An interconnect 103 made of a metal layer is formed on a surface (upper surface in FIG. 3) of the insulating substrate 102 with a seed layer 126 being interposed therebetween. A first insulating film 104 is formed on the insulating substrate 102 and, in addition, on the interconnect 103. Openings 105 are provided in a portion of the first insulating film 104 which covers the interconnect 103 of the first substrate 101.

An inductor 107, a terminal 108, and a terminal 109 which are all made of a metal layer are formed on the first insulating film 104 with a seed layer 129 being interposed therebetween. In the openings 105, the seed layer 129 is connected to the interconnect 103. As shown in FIG. 4, the inductor 107 has a spiral shape as viewed from the top. An outer end portion of the inductor 107 is connected to the terminal 108, and an inner end portion of the inductor 107 is connected to the terminal 109 via the seed layer 129 and the interconnect 103. In other words, the terminals 108 and 109 provide an electrical connection to the inductor 107.

Two electrodes 111 and a shield layer 113 which are made of a metal layer, and a second insulating film 114 are formed on a surface (lower surface in FIG. 3) opposite to the inductor 107 of the insulating substrate 102. The shield layer 113 is mostly covered with the second insulating film 114, leaving only a portion thereof exposed. The portion of the shield layer 113 forms an electrode 112. The electrode 111 is almost entirely exposed without being covered with the second insulating film 114.

Here, as shown in FIGS. 3 and 4, the shield layer 113 is formed in a region which coincides with a region in which the inductor 107 is formed, as viewed in the thickness direction of the first substrate 101. The two electrodes 111 are located to coincide with the terminals 108 and 109, respectively, as viewed in the thickness direction of the first substrate 101. Moreover, first through-vias 116 made of a metal film which penetrate the first substrate 101 and the first insulating film 104 are formed, via which the two electrodes 111 are electrically connected to the terminals 108 and 109, respectively.

Next, the second substrate 117 will be described. As shown in FIG. 1, the second substrate 117 includes a silicon substrate 118. An integrated circuit including active elements 119 is provided on the silicon substrate 118, and is covered with a third insulating film 120. Electrodes 122 and 123 made of a metal layer are formed and embedded in the third insulating film 120. An opening is formed in the third insulating film 120 directly above each of the electrodes 122 and 123.

The first substrate 101 is mounted on the second substrate 117. In this case, the electrode 112 of the shield layer 113 of the first substrate 101 is connected to the electrode 123 of the second substrate 117 via the corresponding metal bump 125. The electrodes 111 of the first substrate 101 are similarly connected to the electrodes 122 of the second substrate 117 via the corresponding metal bumps 125. Note that the electrode 123 electrically connected to the shield layer 113 is a ground electrode.

FIG. 2 shows integrated circuits 140 provided in the second substrate 117, and the first substrate 101 stacked and provided on the second substrate 117. The integrated circuits 140 are a logic circuit, a memory circuit, and the like including the active elements 119. Because these circuits have large sizes, the second substrate 117 has a larger chip size than that of the first substrate 101. Therefore, a two-dimensional size of the semiconductor device 100 is determined by that of the second substrate 117.

In the semiconductor device 100 of this embodiment, the shield layer 113 provided on the first substrate 101 allows the first substrate 101 to be disposed directly above or overlapping the integrated circuits 140 of the second substrate 117.

Specifically, the shield layer 113 can interrupt the magnetic flux generated by the inductor 107. Therefore, even if the integrated circuits 140 are located directly below the inductor 107, the active elements 119 included in the integrated circuits 140 can be hindered or prevented from being affected by the magnetic flux. As a result, a layout constraint that an integrated circuit is prohibited from being located directly below a passive element, such as an inductor or the like, which is required in the conventional art, is no longer imposed on the semiconductor device 100 of this embodiment.

Thus, according to the semiconductor device 100 of this embodiment, the first substrate 101 and its passive element (the inductor 107) have a high degree of layout flexibility with respect to the second substrate 117 including the integrated circuits 140. Moreover, it is not necessary to provide, for the first substrate 101, a region of the second substrate 117 in which an integrated circuit is not provided, whereby the size of the second substrate 117 can be reduced. Thus, the chip size of the semiconductor device 100 can be reduced.

Note that the electrode 112 which is a lead electrode for the shield layer 113 is directly connected to the electrode 123 provided on the second substrate 117 via the corresponding metal bump 125. Therefore, it is not necessary to provide a lead interconnect extending two-dimensionally outside a region in which the shield layer 113 is formed, and the electrode 112 can be provided at substantially any location in the region in which the shield layer 113 is formed.

In this embodiment, only one inductor 107 is provided. In this case, there are a total of at least three electrodes 111 and 112 provided in the first substrate 101. A larger number of electrodes may be provided. For example, as shown in FIG. 6, electrodes 141 may be provided at four corners of the first substrate 101, and electrodes may also be provided at corresponding locations in the second substrate 117. In this case, the first substrate 101 can be supported at the four corners, whereby the first substrate 101 is hindered or prevented from tilting when the first substrate 101 is joined to the second substrate 117, a sufficient bonding strength between the first substrate 101 and the second substrate 117 is ensured, and the like.

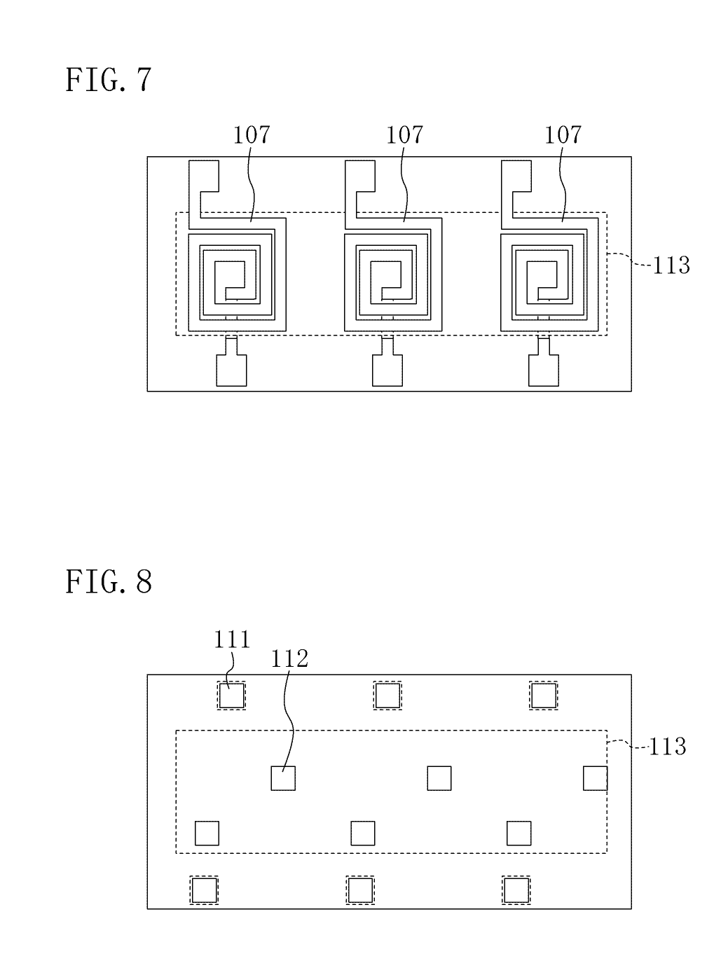

Moreover, when a plurality of inductors need to be provided in the semiconductor device 100, the inductors may be formed in the first substrate 101 as shown in FIG. 7 (three inductors 107 are shown). As described above, in this embodiment, there is not a constraint on the arrangement of the inductors 107 with respect to the integrated circuits 140 including the active elements 119.

The inductors 107 are each electrically connected to the second substrate 117 via the corresponding first through-via 116, electrode 111, and the like. In this case, as shown in FIG. 8, larger numbers of electrodes 111 and electrodes 112 than those required when only one inductor 107 is provided are provided, whereby again the first substrate 101 is hindered or prevented from tilting when the first substrate 101 is joined to the second substrate 117, a sufficient bonding strength between the first substrate 101 and the second substrate 117 is ensured, and the like.

Moreover, the flexible layout of the lead electrode 112 of the shield layer 113 allows a large number of electrodes 112 to be formed, whereby again the first substrate 101 is hindered or prevented from tilting when the first substrate 101 is joined to the second substrate 117, a sufficient bonding strength between the first substrate 101 and the second substrate 117 is ensured, and the like.

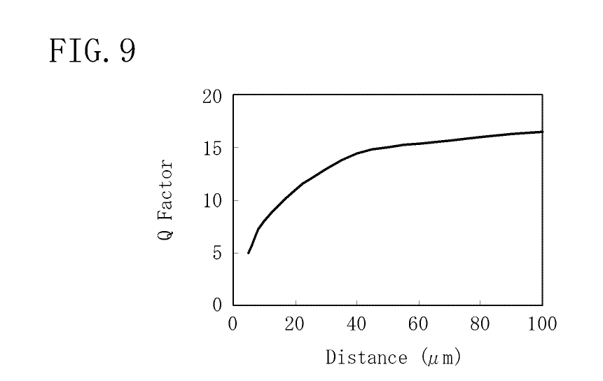

When a shield layer is provided in order to interrupt magnetic flux generated by an inductor, then if a commonly used multilayer interconnection technique or a commonly used redistribution line technique employing an insulating resin film or the like is used, the distance between the inductor and the shield layer is, for example, about 1-50 μm. In this case, as shown in FIG. 9, the Q factor of the inductor may decrease due to the parasitic capacitance between the inductor and the shield layer.

In contrast to this, in this embodiment, the distance between the inductor 107 and the shield layer 113 provided on the opposite surfaces of the first substrate 101 can be about 100-300 μm. As a result, the parasitic capacitance can be reduced, whereby the decrease in the Q factor can be reduced or prevented.

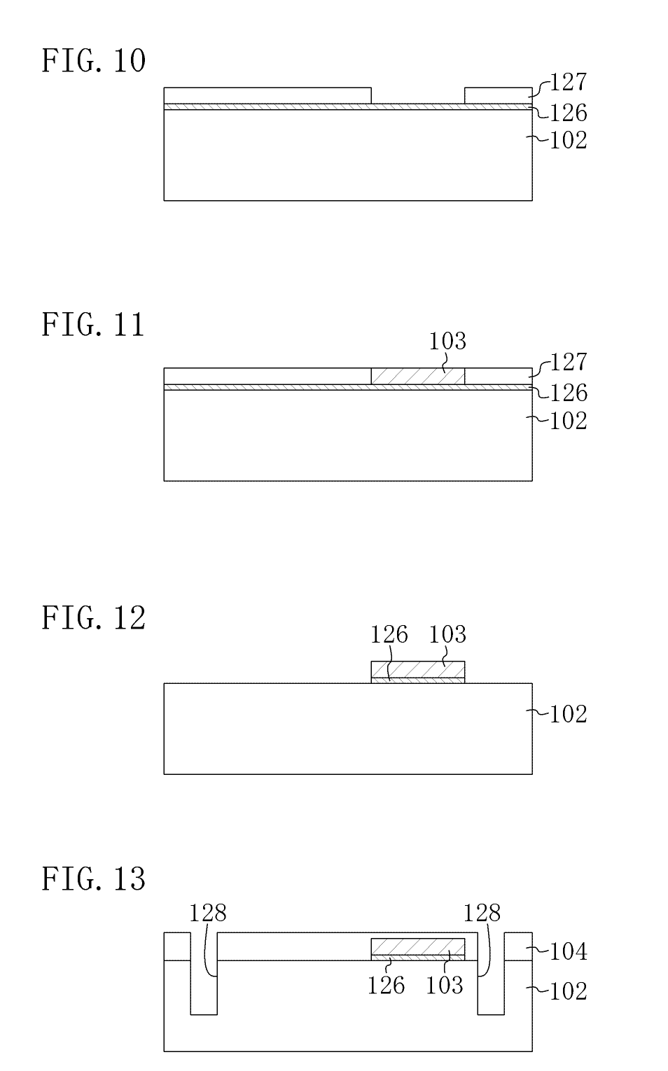

Next, a method for fabricating the semiconductor device 100 will be described. Firstly, a method for fabricating the first substrate 101 will be described with reference to FIGS. 10-20 which are cross-sectional views for describing fabrication steps.

Initially, as shown in FIG. 10, the seed layer 126 made of Cu is formed on the insulating substrate 102 by electroless plating. In this case, in order to enhance the adhesion between the seed layer 126 and the underlying insulating substrate 102, a film made of Cr, Ni, Pt, or the like may be formed on the insulating substrate 102, and the seed layer 126 may be formed on the film. Next, a resist pattern 127 is formed on the seed layer 126 by lithography.

Next, as shown in FIG. 11, a metal film is deposited by electrolytic plating to form the interconnect 103. The metal film may be made of Cu or the like. Because Cu is not deposited in a region in which the resist pattern 127 is formed, the interconnect 103 is formed only in a region in which the seed layer 126 is exposed.

Next, a step shown in FIG. 12 is performed. Initially, the resist pattern 127 is removed. Thereafter, the seed layer 126 in a region which has been covered with the resist pattern 127 is removed by wet etching.

Next, a step shown in FIG. 13 is performed. Initially, the first insulating film 104 is deposited on the insulating substrate 102 and, in addition, on the interconnect 103 by plasma-enhanced chemical vapor deposition (CVD) or the like. Next, first connection holes 128 having a depth of about 100-300 μm and a diameter of about 20-50 μm are formed in the first insulating film 104 and the insulating substrate 102 by, for example, forming a resist pattern on the first insulating film 104 by lithography and then performing dry etching. Thereafter, the resist pattern is removed.

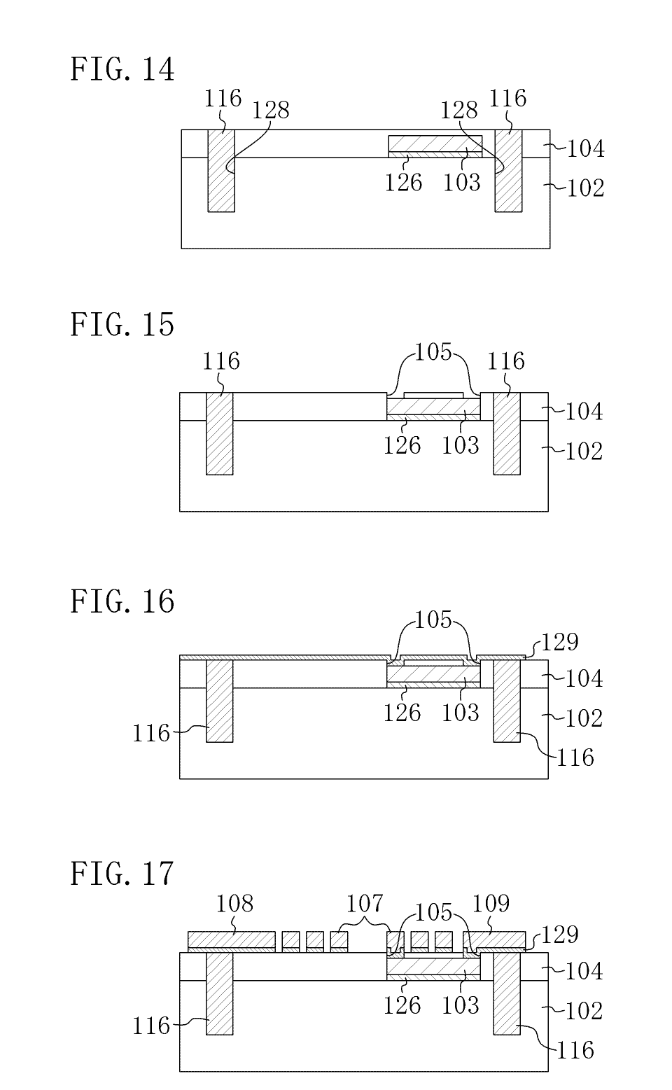

Next, a step shown in FIG. 14 is performed. Initially, a metal film is deposited in the first connection hole 128 and on the first insulating film 104 by CVD. The metal film may be made of W, Cu, or the like. Next, the metal film extending off the first connection holes 128 is removed by chemical mechanical polishing (CMP). As a result, the first through-vias 116 are provided in the first connection holes 128 (the first connection holes 128 are filled with the material for first through-vias 116).

Next, as shown in FIG. 15, the openings 105 are formed in the first insulating film 104 provided on the interconnect 103 by, for example, forming a resist pattern on the first insulating film 104 by lithography and then performing dry etching. Thereafter, the resist pattern is removed.

Next, a step shown in FIG. 16 is performed. The seed layer 129 made of Cu is formed by electroless plating to cover the first insulating film 104 and the openings 105 formed in the first insulating film 104. In this case, in order to enhance the adhesion between the seed layer 129 and the underlying first insulating film 104 and opening 105, a film made of Cr, Ni, Pt, or the like may be formed on the first insulating film 104 and the openings 105, and the seed layer 129 may be formed on the film.

Next, as shown in FIG. 17, the seed layer 129 and a metal film deposited on the seed layer 129 are patterned to form the inductor 107, the terminal 108, and the terminal 109 as follows. Initially, a resist pattern is formed on the seed layer 129 by lithography. Next, the metal film is deposited by electrolytic plating. The metal film is made of, for example, Cu. In this case, Cu is not deposited in a region in which the resist pattern is formed, and the metal film is deposited only in a region in which the seed layer 129 is exposed. In other words, the resist is formed in a region in which the metal film is not to be formed.

Thereafter, the resist pattern is removed, and the seed layer 129 in a region which has been covered with the resist pattern is removed. As a result, a structure shown in FIG. 17 is obtained.

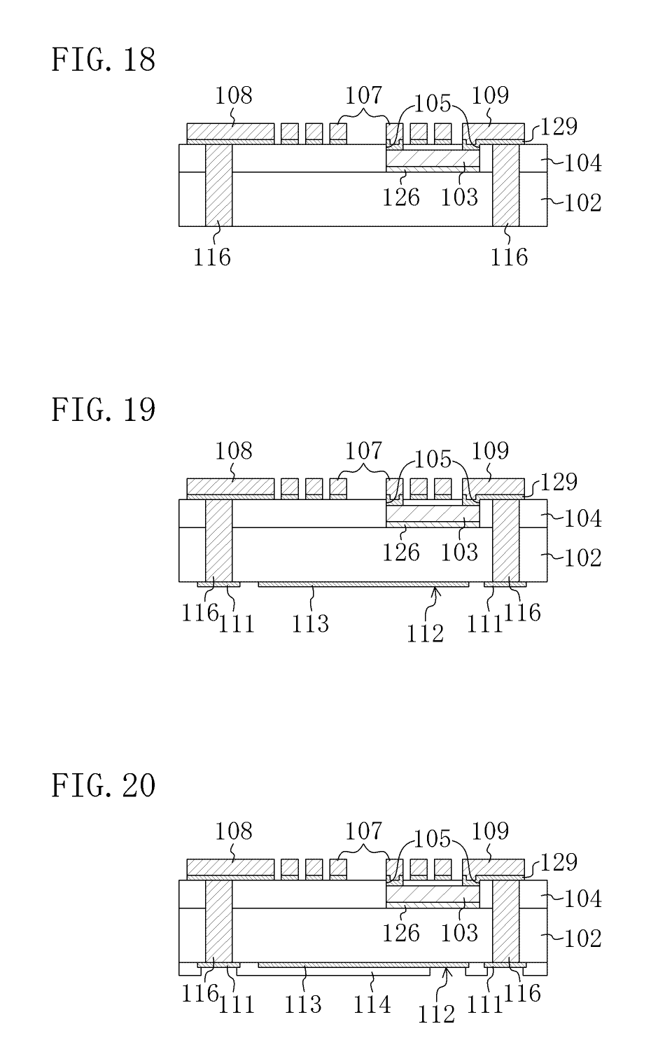

Next, a step shown in FIG. 18 is performed. Here, the insulating substrate 102 is thinned from the lower surface thereof (a surface opposite to the surface on which the inductor 107 and the like are formed), to expose the first through-vias 116 on the lower surface of the insulating substrate 102. The thinning may be performed by, for example, polishing.

Next, a step shown in FIG. 19 is performed. Initially, a metal film is deposited on the lower surface of the insulating substrate 102 by sputtering or the like. The metal film may be made of Al or the like. Next, the metal film is patterned by lithography, dry etching, or the like. Specifically, the patterning is performed so that the metal film is left in regions in which the first through-vias 116 are exposed and a region in which the inductor 107 is formed. As a result, the electrodes 111 which are connected to the first through-vias 116, and the shield layer 113 are formed.

Next, a step shown in FIG. 20 is performed. Initially, the second insulating film 114 is formed on the lower surface of the insulating substrate 102 by CVD or the like to cover the shield layer 113 and the electrodes 111. Next, dry etching or the like is performed with respect to the second insulating film 114 to expose the electrodes 111, and a portion of the shield layer 113 which is to form the electrode 112.

By the aforementioned illustrative steps, the first substrate 101 of this embodiment is formed.

On the other hand, the second substrate 117 is formed using the silicon substrate 118. Initially, the integrated circuit including the active elements 119 is formed on the silicon substrate 118 using a known technique. Next, the third insulating film 120 covering the active elements 119, and the electrodes 122 and 123 embedded in the third insulating film 120 are formed on the silicon substrate 118. Note that openings are formed in the third insulating film 120 directly above the electrodes 122 and 123 so that the electrodes 122 and the electrode 123 are exposed in the openings.

Note that the electrodes 122 and 123 of the second substrate 117 are formed at locations respectively corresponding to the electrodes 111 and 112 provided on the lower surface of the first substrate 101.

By mounting the first substrate 101 onto the second substrate 117, the semiconductor device 100 of this embodiment is provided.

In order to mount the first substrate 101 onto the second substrate 117, the metal bump 125 is formed on each of the electrodes 122 and 123 of the second substrate 117, and the electrodes 111 and 112 provided on the lower surface of the first substrate 101 are pressed against and joined to the metal bumps 125. The metal bumps 125 are made of, for example, solder. Alternatively, the metal bumps 125 may be formed on the electrodes 111 and 112 provided on the first substrate 101 before the first substrate 101 is mounted onto the second substrate 117.

Thus, the inductor 107 of the first substrate 101 is electrically connected to the second substrate 117. The lead electrode 112 of the shield layer 113 of the first substrate 101 is electrically connected to the electrode 123 of the second substrate 117, and the electrode 123 is grounded.

### Second Embodiment

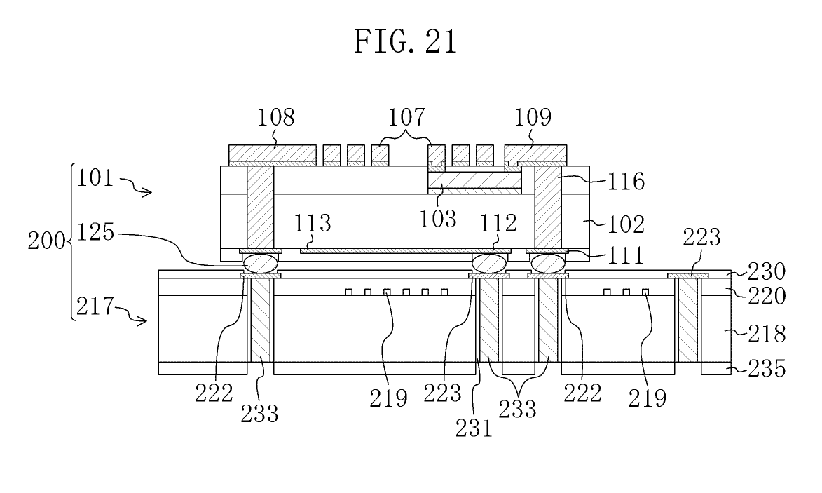

A semiconductor device according to a second embodiment of the present disclosure will be described hereinafter with reference to the drawings. FIG. 21 is a cross-sectional view showing the semiconductor device 200 of this embodiment. As shown in FIG. 21, the semiconductor device 200 has a structure in which a first substrate 101 is mounted on a second substrate 217 with metal bumps 125 being interposed therebetween.

Here, the first substrate 101 is the same as that of the first embodiment.

The second substrate 217 of this embodiment includes a silicon substrate 218. An integrated circuit including active elements 219 is provided on the silicon substrate 218, and is covered with a third insulating film 220. Electrodes 222 and 223 made of a metal film, and a fourth insulating film 230 having openings on the electrodes 222 and 223, are formed on the third insulating film 220.

Second through-vias 233 are formed which penetrate the silicon substrate 218 and the third insulating film 220 and are connected to the electrodes 222 and 223. The second through-vias 233 are each made of a metal film which fills a through-hole whose side wall is covered with a fifth insulating film 231. The lower surface of the silicon substrate 218 (a surface opposite to the surface on which the active elements 219 and the like are formed) is covered with a sixth insulating film 235, except for portions thereof corresponding to the second through-vias 233.

The first substrate 101 is mounted on the second substrate 217. Here, the electrodes 111 and 112 formed in the first substrate 101 are connected to the electrodes 222 and 223 formed in the second substrate 217 via the metal bumps 125.

The second through-vias 233 provided in the second substrate 217 are exposed on a surface opposite to the surface connected to the first substrate 101, and the exposed portions are connected to a mounting substrate.

Thus, the semiconductor device 200 of this embodiment is mounted using the second through-vias 233. Therefore, the semiconductor device 200 can be incorporated into a small-size package, such as a chip scale package (CSP) or the like, resulting in a smaller mounting area.

The advantage of providing the shield layer 113 is similar to that of the semiconductor device 100 of the first embodiment. Specifically, the shield layer 113 interrupts magnetic flux generated by the inductor 107, which would otherwise affect the active elements 219.

Terminals 108 and 109 which provide an electrical connection to the inductor 107 are connected to the mounting substrate via the first through-vias 116, the electrodes 111, the metal bumps 125, the electrodes 222, and the second through-vias 233. As a result, the inductor 107 can be electrically connected to the mounting substrate, but not via a fine interconnect (e.g., an interconnect having a line width of 0.18-0.25 μm) in the integrated circuit formed on the second substrate 217. Note that, to achieve this, the first through-vias 116 and the second through-vias 233 are arranged to coincide with each other as viewed from the top.

The fine interconnect in the integrated circuit has a large parasitic resistance. Therefore, if a high frequency signal is transmitted through the fine interconnect, there is a large transmission loss. Therefore, by electrically connecting the inductor 107 to the mounting substrate via the first through-vias 116, the second through-vias 233, and the like as in this embodiment, but not via a fine interconnect in the integrated circuit, the transmission loss can be reduced or avoided.

The electrode 112 which provides an electrical connection to the shield layer 113 is connected to a ground electrode of the mounting substrate via the corresponding metal bump 125, electrode 223, and second through-via 233. As a result, the shield layer 113 can be electrically connected to the mounting substrate, but not via a fine interconnect provided in the integrated circuit. The parasitic resistance can be caused to be smaller than when the shield layer 113 is electrically connected to the mounting substrate via a fine interconnect. Therefore, the second through-via 233 may be disposed so that the position of the second through-via 233 falls within the range of the shield layer 113 as viewed from the top.

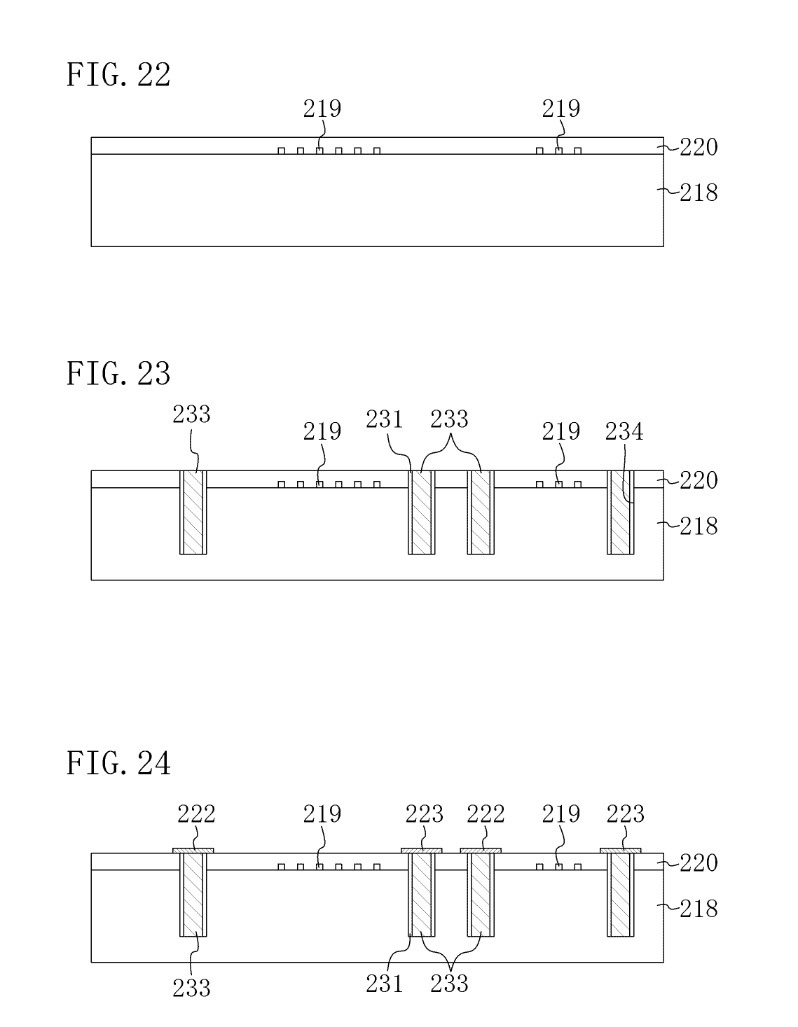

Next, a method for fabricating the semiconductor device 200 will be described. The first substrate 101 may be formed in a manner similar to that described in the first embodiment. Therefore, the second substrate 217 will be described hereinafter. FIGS. 22-27 are cross-sectional views showing fabrication steps of the second substrate 217.

Initially, as shown in FIG. 22, the integrated circuit including the active elements 219 and the third insulating film 220 covering the integrated circuit are formed on the silicon substrate 218 using a known technique.

Next, a step shown in FIG. 23 is performed. Initially, a resist pattern is formed on the third insulating film 220 by lithography, and connection holes 234 are formed in the third insulating film 220 and the silicon substrate 218 by dry etching or the like. The connection holes 234 have a depth of about 100-300 μm and a diameter of about 20-50 μm. Thereafter, the resist pattern is removed.

Thereafter, the fifth insulating film 231 and a metal film are successively deposited on the connection holes 234 and the third insulating film 220 by CVD. The metal film may be made of W, Cu, or the like.

Thereafter, the fifth insulating film 231 and the metal film extending off the connection holes 234 are removed by CMP. As a result, the sidewalls of the connection holes 234 are covered with the fifth insulating film 231, and the second through-vias 233 made of the metal film are formed in the connection holes 234 inside the fifth insulating film 231.

Next, a step shown in FIG. 24 is performed. Here, a metal film is deposited on the third insulating film 220 by sputtering or the like. The metal film is made of Al or the like. Next, the metal film is patterned by lithography and dry etching. As a result, the electrodes 222 and 223 are formed on the second through-vias 233.

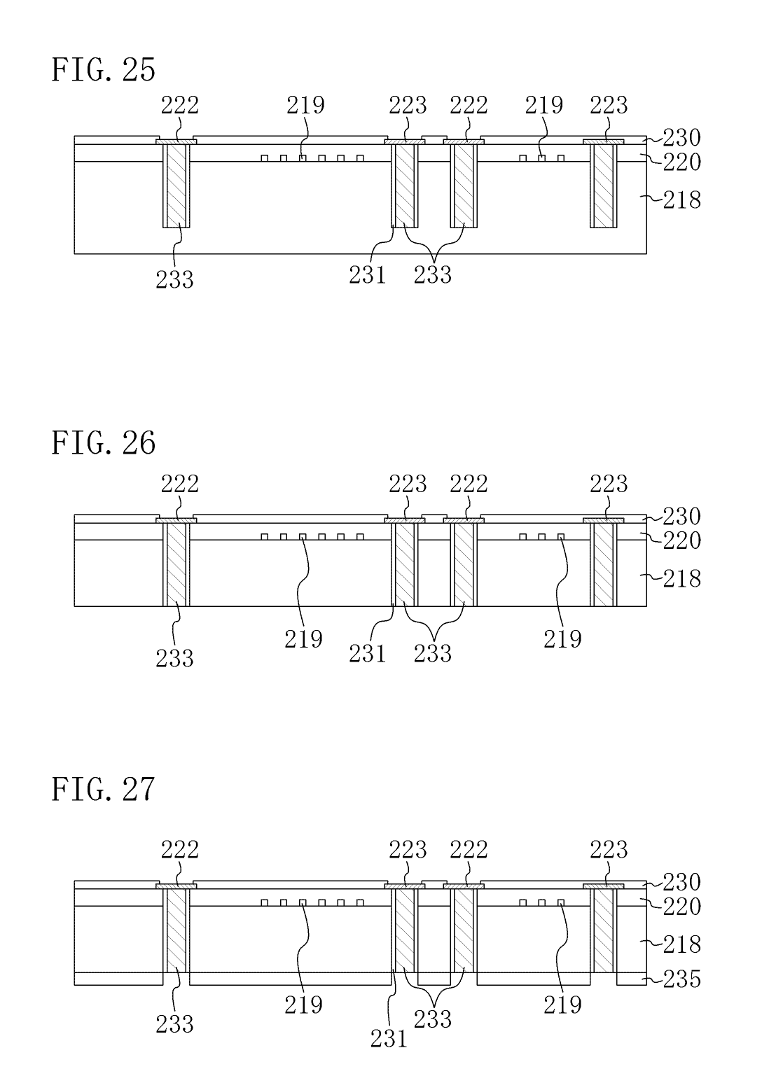

Next, a step shown in FIG. 25 is performed. Initially, the fourth insulating film 230 is formed on the third insulating film 220 and, in addition, on the electrodes 222 and 223 by CVD. Next, openings are provided in the fourth insulating film 230 directly above the electrodes 222 and 223 which are to be contacted to the first substrate 101, by lithography and dry etching.

Here, the electrodes 222 and 223 are provided so that the positions of the electrodes 222 and 223 coincide with those of the electrodes 111 and 112 of the first substrate 101. The electrode 223 of the second substrate 217 which corresponds to the electrode 112 which provides an electrical connection to the shield layer 113 of the first substrate 101, serves as an electrode which is grounded via the corresponding second through-via 233.

Next, a step shown in FIG. 26 is performed. Here, the silicon substrate 218 is thinned from the lower surface thereof by polishing or the like so that the second through-vias 233 are exposed on the lower surface of the silicon substrate 218.

Next, a step shown in FIG. 27 is performed. Here, the sixth insulating film 235 is deposited on the lower surface of the silicon substrate 218 by CVD. Thereafter, the sixth insulating film 235 is patterned by lithography and dry etching to expose the second through-vias 233.

By the aforementioned steps, the second substrate 217 is fabricated.

By mounting the first substrate 101 onto the second substrate 217, the semiconductor device 200 of this embodiment is provided.

In order to mount the first substrate 101 onto the second substrate 217, the metal bumps 125 are formed on the electrodes 222 and 223 exposed on the second substrate 217. Next, the electrodes 111 and 112 of the first substrate 101 are pressed against and joined to the electrodes 222 and 223 of the second substrate 217 via the metal bumps 125. Here, the metal bumps 125 may be made of solder. Alternatively, the metal bumps 125 may be formed on the electrodes 111 and 112 of the first substrate 101 before the first substrate 101 is mounted onto the second substrate 217.

According to the aforementioned semiconductor devices, when a plurality of chips are stacked, a passive element and an active element are allowed to be disposed so that one is located directly above the other or they overlap each other as viewed in the thickness direction, resulting in an increase in the flexibility of layout and a reduction in the device size. Therefore, the present disclosure is useful for semiconductor devices having smaller sizes.

What is claimed is:

1. A semiconductor device comprising:
a first substrate having a first surface and a second surface, wherein a passive element is formed on the first surface and a shield layer is formed on the second surface; and
a second substrate having a first surface and a second surface, wherein an active element is formed on the first surface,
wherein
the first substrate is mounted on the second substrate with the second surface of the first substrate facing the second substrate.

2. The semiconductor device of claim 1, further comprising:
at least one second through-via penetrating the second substrate.

3. The semiconductor device of claim 2, further comprising:
at least one first through-via penetrating the first substrate,
wherein
the passive element is electrically connected to the at least one second through-via via the at least one first through-via.

4. The semiconductor device of claim 3, wherein
the passive element is electrically connected to the at least one second through-via, but not via interconnects in integrated circuits formed in the first and second substrates.

5. The semiconductor device of claim 2, wherein
the shield layer is electrically connected to the at least one second through-via.

6. The semiconductor device of claim 5, wherein
the shield layer is electrically connected to the at least one second through-via, but not via interconnects in integrated circuits formed in the first and second substrates.

7. The semiconductor device of claim 2, wherein
the semiconductor device is connected to a mounting substrate via the at least one second through-via exposed on the second surface of the second substrate.

8. The semiconductor device of claim 1, wherein
the first substrate is an insulating substrate.

9. The semiconductor device of claim 1, wherein
the passive element provided on the first substrate is an inductor.

10. The semiconductor device of claim 1, wherein
the shield layer is a metal layer.
